(19) United States
(12) Patent Application Publication
(10) Pub. No.: US 2025/0304800 A1
(43) Pub. Date: Oct. 2, 2025

(54) DISPERSION LIQUID, PHOTOELECTRIC CONVERSION FILM, METHOD FOR MANUFACTURING PHOTOELECTRIC CONVERSION FILM, PHOTODETECTOR, AND IMAGE SENSOR

(71) Applicant: FUJIFILM Corporation, Tokyo (JP)

(72) Inventors: Yasuhiro SAWAMURA, Shizuoka (JP); Takashi GOTO, Shizuoka (JP); Atsuko TABUCHI, Shizuoka (JP)

(73) Assignee: FUJIFILM Corporation, Tokyo (JP)

(21) Appl. No.: 19/236,668

(22) Filed: Jun. 12, 2025

Related U.S. Application Data
(63) Continuation of application No. PCT/JP2024/002209, filed on Jan. 25, 2024.

(30) Foreign Application Priority Data
Feb. 6, 2023 (JP) 2023-015908

(51) Int. Cl. C09D 5/24; B82Y 15/00; B82Y 40/00; C09D 7/62; G01J 1/44; H10F 77/45

(52) U.S. Cl. CPC C09D 5/24; C09D 7/62; G01J 1/44; B82Y 15/00; B82Y 40/00; G01J 2001/446; H10F 77/45

(57) ABSTRACT

A dispersion liquid including quantum dots having a band gap of 1.35 eV or less; a ligand; and a solvent, in which a content of the quantum dots in a component obtained by removing the solvent and the ligand from the dispersion liquid is 50% by mass or more, and the ligand contains a compound having a pKa of 3 or less or a salt of the compound. A photoelectric conversion film using a dispersion liquid, a method for manufacturing a photoelectric conversion film, a photodetector, and an image sensor.

### CROSS-REFERENCE TO RELATED APPLICATIONS

This application is a Continuation of PCT International Application No. PCT/JP2024/002209 filed on Jan. 25, 2024, which claims priority under 35 U.S.C § 119(a) to Japanese Patent Application No. 2023-015908 filed on Feb. 6, 2023. Each of the above application(s) is hereby expressly incorporated by reference, in its entirety, into the present application.

### BACKGROUND OF THE INVENTION

### 1. Field of the Invention

The present invention relates to a dispersion liquid containing quantum dots. In addition, the present invention relates to a photoelectric conversion film, a method for manufacturing a photoelectric conversion film, a photodetector, and an image sensor.

### 2. Description of the Related Art

In recent years, attention has been focused on photodetectors capable of detecting light in the infrared region in the fields such as smartphones, surveillance cameras, and in-vehicle cameras.

In the related art, a silicon photodiode in which a silicon wafer is used as a material of a photoelectric conversion film has been used in a photodetector that is used for an image sensor or the like. However, a silicon photodiode has low sensitivity in the infrared region having a wavelength of 900 nm or more.

In addition, an InGaAs-based semiconductor material known as a near-infrared light-receiving element has a problem in that it requires extremely high-cost processes such as epitaxial growth or a step of bonding a substrate in order to realize a high quantum efficiency, and thus it has not been widely adopted.

In addition, in recent years, the use of the quantum dot for a photoelectric conversion element has been being studied. For example, JP2020-150251A describes that quantum dots containing inorganic particles are used for a photoelectric conversion film of a photoelectric conversion element, where the quantum dots have organic ligands and inorganic ligands on their surfaces, and a molar ratio of the inorganic ligands to a total of the inorganic ligands and the organic ligands is 25% or more and 99.8% or less.

### SUMMARY OF THE INVENTION

In recent years, with the demand for performance improvement of an image sensor and the like, there is a demand for further improvement of various characteristics that are required in a photodetector used in the image sensor and the like. For example, as the characteristics required for the photodetector, it is required to have a high external quantum efficiency with respect to light having a target wavelength to be detected by the photodetector.

On the other hand, in general, a ligand having a long molecular chain length, such as oleic acid, is used for a dispersion liquid of quantum dots in order to improve the dispersibility of the quantum dots in the dispersion liquid. However, in a case where a quantum dot film such as the photoelectric conversion film is formed by using a dispersion liquid containing such a ligand having the long molecular chain length, a distance between the quantum dots tends to be long, sufficient optical response is not obtained, and thus the external quantum efficiency tends to be low.

Therefore, after forming a film using a dispersion liquid of quantum dots, a ligand solution is applied onto the film to exchange the ligand coordinated to the quantum dots in the film with another ligand. Also in JP2020-150251A, after forming a film using a quantum dot dispersion liquid, a ligand solution is applied onto the film to exchange the ligand.

As described above, in the dispersion liquid of quantum dots known so far, it is necessary to carry out a ligand exchange treatment in order to form a quantum dot film having a high external quantum efficiency, which is time-consuming and results in an increase in cost.

Therefore, an object of the present invention is to provide a dispersion liquid that enables formation of a quantum dot film having excellent dispersibility and high external quantum efficiency. In addition, another object of the present invention is to provide a photoelectric conversion film, a method for manufacturing a photoelectric conversion film, a photodetector, and an image sensor.

The present invention provides the following aspects.
<1> A dispersion liquid comprising:
quantum dots having a band gap of 1.35 eV or less;
a ligand; and
a solvent,
in which a content of the quantum dots in a component obtained by removing the solvent and the ligand from the dispersion liquid is 50% by mass or more, and
the ligand contains a compound having a pKa of 3 or less or a salt of the compound.
<2> The dispersion liquid according to <1>, in which a molecular weight of the compound having a pKa of 3 or less is 50 to 500.
<3> The dispersion liquid according to <1>or <2>, in which the compound having a pKa of 3 or less is a compound having at least one functional group selected from the group consisting of a carboxy group, a phospho group, a phosphonic acid group, a sulfonimide group, and a sulfo group.
<4> The dispersion liquid according to <1> or <2>, in which the compound having a pKa of 3 or less is a compound having at least one functional group selected from the group consisting of a phospho group and a phosphonic acid group.
<5> The dispersion liquid according to any one of <1> to <4>, in which the quantum dots contain at least one atom selected from the group consisting of Ga, Ge, P, As, Se, In, Sn, Sb, Te, Pb, Bi, Ag, Cu, and Hg.
<6> The dispersion liquid according to any one of <1> to <4>, in which the quantum dots contain at least one atom selected from the group consisting of P, As, Sb, and In.
<7> The dispersion liquid according to any one of <1> to <6>, in which the quantum dots have a maximal absorption in terms of absorbance in a wavelength range of 900 to 1,700 nm.
<8> A photoelectric conversion film obtained by using the dispersion liquid according to any one of <1> to <7>.
<9> A method for manufacturing a photoelectric conversion film, comprising:
applying the dispersion liquid according to any one of <1> to <7> onto a support to form a composition layer; and
drying the composition layer.
<10> A photodetector comprising the photoelectric conversion film according to <8>.
<11> An image sensor comprising the photoelectric conversion film according to <8>.

According to the present invention, it is possible to provide a dispersion liquid that enables formation of a quantum dot film having excellent dispersibility and high external quantum efficiency. In addition, it is possible to provide a photoelectric conversion film, a method for manufacturing a photoelectric conversion film, a photodetector, and an image sensor.

### BRIEF DESCRIPTION OF THE DRAWING

FIG. 1 is a view illustrating an embodiment of a photodetector.

### DESCRIPTION OF THE PREFERRED EMBODIMENTS

Hereinafter, the details of the present invention will be described.

In the present specification, “to” is used to mean that numerical values described before and after “to” are included as a lower limit value and an upper limit value, respectively.

In describing a group (an atomic group) in the present specification, in a case where a description of substitution and non-substitution is not provided, the description means the group includes a group (an atomic group) having a substituent as well as a group (an atomic group) having no substituent. For example, the “alkyl group” includes not only an alkyl group that does not have a substituent (an unsubstituted alkyl group) but also an alkyl group that has a substituent (a substituted alkyl group).

### Dispersion Liquid

A dispersion liquid according to the embodiment of the present invention includes quantum dots having a band gap of 1.35 eV or less; a ligand; and a solvent, in which a content of the quantum dots in a component obtained by removing the solvent and the ligand from the dispersion liquid is 50% by mass or more, and the ligand contains a compound having a pKa of 3 or less or a salt thereof.

The dispersion liquid according to the embodiment of the present invention contains a compound having a pKa of 3 or less or a salt thereof as a ligand. It is presumed that the above-described ligand is easily coordinated to the quantum dots, and the quantum dots are electrostatically repelled by the above-described ligand coordinated to the surfaces of the quantum dots, thereby suppressing the aggregation of the quantum dots in the dispersion liquid. Therefore, the dispersion liquid according to the embodiment of the present invention has excellent dispersibility. In addition, it is presumed that, during the film formation, the distance between the quantum dots in the film can be further reduced by the polar interaction of the above-described ligand coordinated to the surfaces of the quantum dots. Therefore, the dispersion liquid according to the embodiment of the present invention can form a quantum dot film having a high external quantum efficiency without performing a ligand exchange step or the like.

The quantum dot film obtained by using the dispersion liquid according to the embodiment of the present invention can be used for a photodetector or an image sensor. More specifically, the quantum dot film can be used for a photoelectric conversion film of a photodetector or an image sensor. Therefore, the dispersion liquid according to the embodiment of the present invention is preferably used for a photoelectric conversion film of a photodetector or an image sensor. In addition, since the quantum dot film obtained by using the dispersion liquid according to the embodiment of the present invention has excellent sensitivity to light having a wavelength in the infrared region. Therefore, the image sensor in which the quantum dot film obtained by using the dispersion liquid according to the embodiment of the present invention is used for the photoelectric conversion film can be particularly preferably used as an infrared sensor. Therefore, the dispersion liquid according to the embodiment of the present invention is preferably used as a dispersion liquid for a photoelectric conversion film of an infrared sensor.

Hereinafter, the dispersion liquid according to the embodiment of the present invention will be described in more detail.

### Quantum Dots

The dispersion liquid according to the embodiment of the present invention contains quantum dots. The quantum dots are preferably a semiconductor particle including a metal atom. Furthermore, in the present specification, the metal atom also includes a metalloid atom typified by an Si atom. In addition, the “semiconductor” in the present specification means a substance having a specific resistance value of 10⁻² Ω cm or more and 10⁸ Ω cm or less.

Examples of the quantum dot material constituting the quantum dot include nanoparticles (a particle having a size of 0.5 nm or more and less than 100 nm) of general semiconductor crystals [a) a Group IV semiconductor, b) a compound semiconductor of Group IV-IV, Group III-V, or Group II-VI, or c) a compound semiconductor consisting of a combination of three or more of a Group II element, a Group III element, a Group IV element, a Group V element, and a Group VI element].

The quantum dots are preferably quantum dots including at least one kind of atom selected from the group consisting of Ga, Ge, P, As, Se, In, Sn, Sb, Te, Pb, Bi, Ag, Cu, and Hg, and more preferably quantum dots including at least one kind of atom selected from the group consisting of Ga, P, As, Se, In, Sb, Te, and Bi.

The quantum dots containing Pb atoms are exemplified as a preferred aspect of the quantum dots.

Another preferred aspect of the quantum dots is quantum dots containing In atoms. The quantum dots in the present aspect are preferably quantum dots containing In atoms and at least one atom selected from Sb atoms or As atoms.

Another preferred aspect of the quantum dots is quantum dots containing Ag atoms and Bi atoms.

Specific examples of the quantum dot material constituting the quantum dots include semiconductor materials having a relatively narrow band gap, such as PbS, PbSe, PbSeS, InN, Ge, InAs, InGaAs, CuInS, CuInSe, CuInGaSe, InSb, HgTe, HgCdTe, Ag₂S, Ag₂Se, Ag₂Te, SnS, SnSe, SnTe, Si, InP, AgBiS₂, and AgBiSTe. Due to the reason that the absorption coefficient of light in the infrared region is large, the lifetime of photocurrent is long, the carrier mobility is large, and the like, the quantum dots are preferably PbS, InAs, InSb, InAsSb, or InPAs.

The band gap of the quantum dots is 1.35 eV or less, and it is preferably 1.1 eV or less and more preferably 1.0 eV or less. A lower limit value of the band gap of the quantum dots is not particularly limited, but can be 0.5 eV or more. In a case where the band gap of the quantum dots is 1.35 eV, it is possible to form a quantum dot film having a higher external quantum efficiency with respect to light having a wavelength in the infrared region. The band gap of the quantum dots can be calculated from the energy at the maximal absorption wavelength in an absorption spectrum obtained from light absorption measurement in a range from the visible region to the infrared region, by using an ultraviolet-visible-near infrared spectrophotometer. In addition, it can be determined from a Tauc plot as described in JP5949567B in a case of quantum dots having no maximal absorption wavelength.

The quantum dots are preferably quantum dots that have a maximal absorption in terms of absorbance in a wavelength range of 900 to 1,700 nm, and it is more preferably such one that has a maximal absorption in terms of absorbance in a wavelength range of 1,300 to 1,600 nm. In a case where such quantum dots are used, it is possible to form a quantum dot film having a higher external quantum efficiency with respect to light having a wavelength in the infrared region.

The quantum dots are also preferably quantum dots that have high absorption with respect to light having any wavelength in a wavelength range of 900 to 1,700 nm (preferably, a wavelength range of 1,300 to 1,600 nm). In a case where such quantum dots are used, it is possible to form a quantum dot film having a higher external quantum efficiency with respect to light having a wavelength in the infrared region.

The average particle diameter of the quantum dots is preferably 3 to 20 nm. The lower limit value of the average particle diameter of the quantum dots is preferably 4 nm or more and more preferably 5 nm or more. The upper limit value of the average particle diameter of the quantum dots is preferably 15 nm or less and more preferably 10 nm or less. In a case where the average particle diameter of the quantum dots is in the above-described range, it is possible to form a quantum dot film having a higher external quantum efficiency with respect to light having a wavelength in the infrared region. It is noted that in the present specification, the value of the average particle diameter of the quantum dots is an average value of the particle diameters of ten quantum dots which are randomly selected. A transmission electron microscope may be used for measuring the particle diameter of the quantum dots.

The content of the quantum dots in the dispersion liquid is preferably 1% to 25% by mass with respect to the total mass of the dispersion liquid. The lower limit thereof is preferably 2% by mass or more and more preferably 3% by mass or more. The upper limit thereof is preferably 20% by mass or less.

In addition, the content of the quantum dots in the dispersion liquid is preferably 10 to 250 mg/mL. The lower limit thereof is preferably 20 mg/mL or more, and more preferably 30 mg/mL or more. The upper limit thereof is preferably 200 mg/mL or less.

In addition, the content of the quantum dots in the component obtained by removing the solvent and the ligand from the dispersion liquid is 50% by mass or more, preferably 60% by mass or more, and more preferably 70% by mass or more. The upper limit thereof may be 100% by mass or less.

In addition, a total content of the quantum dot and the ligand in a component obtained by removing the solvent from the dispersion liquid is preferably 60% by mass or more, more preferably 70% by mass or more, and still more preferably 80% by mass or more. The upper limit thereof may be 100% by mass or less.

### Ligand

The dispersion liquid according to the embodiment of the present invention contains a ligand. As the ligand, a compound having a pKa of 3 or less or a salt thereof is used. Hereinafter, the compound having a pKa of 3 or less and a salt thereof, which are used as the ligand, are also referred to as a specific ligand. In the present specification, the pKa of a compound is a value determined by calculation using software (Advanced Chemistry Development (ACD/Labs) Software V8.14 for Solaris (1994-2007 ACD/Labs)).

### Specific Ligand

As the specific ligand, a salt of a compound having a pKa of 3 or less or the salt thereof is used.

In the “salt of a compound having a pKa of 3 or less”, examples of atoms or atomic groups constituting the compound having a pKa of 3 or less and the salt include a metal ion (Li⁺, Na⁺, K⁺, Ca²⁺, Mg²⁺, Zn²⁺, Cu²⁺, Ga³⁺, In³⁺, Zr⁴⁺, Hf⁴⁺, and the like), an ammonium ion, and the like. That is, examples of the salt of the compound having a pKa of 3 or less include a metal salt of the compound having a pKa of 3 or less and an ammonium salt of the compound having a pKa of 3 or less.

The upper limit of the pKa of the compound having a pKa of 3 or less is preferably 2.5 or less for the reason that a quantum dot film having a further reduced dark current can be formed. The lower limit of the pKa of the above-described compound is preferably −2.0 or more, more preferably −1.0 or more, and still more preferably 0.5 or more for the reason that a quantum dot film having a further reduced dark current can be formed.

The molecular weight of the compound having a pKa of 3 or less is preferably 50 to 500, for the reason that a quantum dot film having a high external quantum efficiency can be formed. The upper limit of the molecular weight is preferably 450 or less and more preferably 400 or less.

The compound having a pKa of 3 or less is preferably a compound having at least one functional group selected from the group consisting of a carboxy group, a phospho group, a phosphonic acid group, a sulfonimide group, and a sulfo group, and more preferably a compound having at least one functional group selected from the group consisting of a phospho group and a phosphonic acid group.

Specific examples of the specific ligand include phenyl phosphonic acid, methanesulfonic acid, trifluoroacetic acid, bromoacetic acid, 3-phosphorylpropionic acid, glycine-N,N-bis(methylenephosphonic acid), 2-chloroethyl phosphonic acid, phenyl phosphate, dimethyl phosphate, trifluoromethanesulfonic acid, and a metal salt (for example, a zinc salt) of these compounds. The specific ligand may include a compound having a phosphoric acid anhydride bond, such as diphosphate, triphosphate, or polyphosphate.

### Other Ligands

The dispersion liquid according to the embodiment of the present invention may further contain a ligand other than the above-described specific ligand. The other ligand may be an organic ligand or may be an inorganic ligand. As the other ligand, an inorganic ligand and an organic ligand can be used in combination.

The inorganic ligand is preferably an inorganic halide. Examples of the halogen atom contained in the inorganic halide include a fluorine atom, a chlorine atom, a bromine atom, and an iodine atom, and a bromine atom or an iodine atom is preferable. In addition, the inorganic halide is preferably a compound containing at least one atom selected from the group consisting of Zn, Cd, Ga, Ge, As, Se, In, Sn, Sb, Te, TI, Pb, Bi, and Po.

Specific examples of the inorganic ligand include zinc iodide, zinc bromide, zinc chloride, indium iodide, indium bromide, indium chloride, cadmium iodide, lead chloride, lead bromide, lead iodide, cadmium bromide, cadmium chloride, gallium iodide, gallium bromide, gallium chloride, potassium sulfide, and sodium sulfide.

The organic ligand is preferably a compound having at least one functional group selected from the group consisting of a carboxy group, a mercapto group, an amino group, and a hydroxy group, and more preferably a compound having at least one functional group selected from the group consisting of a mercapto group and an amino group. The organic ligand may be a monodentate ligand having only one of the above-described functional groups, or may be a multidentate ligand having two or more of the above-described ligands.

Specific examples of the monodentate organic ligand include 2-naphthylamine, 4-methylthioaniline, 4-methylbenzenethiol, 3,5-dimethylbenzenethiol, 4-chlorobenzenethiol, 4-methoxybenzenethiol, and benzoic acid.

Examples of the multidentate ligand include a ligand represented by any of Formulae (A) to (C).

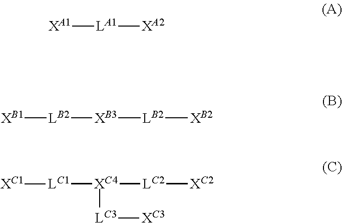

In Formula (A), X^{A1} and X^{A2} each independently represent a carboxy group, a mercapto group, an amino group, or a hydroxy group, and
L^{A1} represents a hydrocarbon group.

In Formula (B), X^{B1} and X^{B2} each independently represent a carboxy group, a mercapto group, an amino group, or a hydroxy group,
X^{B3} represents S, O, or NH, and
L^{B1} and L^{B2} each independently represent a hydrocarbon group.

In Formula (C), X^{C1} to X^{C3} each independently represent a carboxy group, a mercapto group, an amino group, or a hydroxy group,
X^{C4} represents N, and
L^{C1} to L^{C3} each independently represent a hydrocarbon group.

The amino group represented by X^{A1}, X^{A2}, X^{B1}, X^{B2}, X^{C1}, X^{C2}, or X^{C3} is not limited to —NH₂ and includes a substituted amino group and a cyclic amino group as well. Examples of the substituted amino group include a monoalkylamino group, a dialkylamino group, a monoarylamino group, a diarylamino group, and an alkylarylamino group. The amino group represented by these groups is preferably —NH₂, a monoalkylamino group, or a dialkylamino group, and more preferably —NH₂.

The hydrocarbon group represented by L^{A1}, L^{B1}, L^{B2}, L^{C1}, L^{C2}, or L^{C3} is preferably an aliphatic hydrocarbon group or a group including an aromatic ring, and more preferably the aliphatic hydrocarbon group. The aliphatic hydrocarbon group may be a saturated aliphatic hydrocarbon group or may be an unsaturated aliphatic hydrocarbon group. The hydrocarbon group preferably has 1 to 20 carbon atoms. An upper limit of the number of carbon atoms is preferably 10 or less, more preferably 6 or less, and still more preferably 3 or less. Specific examples of the hydrocarbon group include an alkylene group, an alkenylene group, an alkynylene group, and an arylene group.

Examples of the alkylene group include a linear alkylene group, a branched alkylene group, and a cyclic alkylene group. The linear alkylene group or the branched alkylene group is preferable, and the linear alkylene group is more preferable. Examples of the alkenylene group include a linear alkenylene group, a branched alkenylene group, and a cyclic alkenylene group. The linear alkenylene group or the branched alkenylene group is preferable, and the linear alkenylene group is more preferable. Examples of the alkynylene group include a linear alkynylene group and a branched alkynylene group, and the linear alkynylene group is preferable. The arylene group may be a monocyclic ring or may be a polycyclic ring. The monocyclic arylene group is preferable. Specific examples of the arylene group include a phenylene group and a naphthylene group, and the phenylene group is preferable. The alkylene group, the alkenylene group, the alkynylene group, and the arylene group may further have a substituent. The substituent is preferably a group having 1 or more and 10 or less atoms. Preferred specific examples of the group having 1 or more and 10 or less of atoms include an alkyl group having 1 to 3 carbon atoms [a methyl group, an ethyl group, a propyl group, or an isopropyl group], an alkenyl group having 2 or 3 carbon atoms [an ethenyl group or a propenyl group], an alkynyl group having 2 to 4 carbon atoms [an ethynyl group, a propynyl group, or the like], a cyclopropyl group, an alkoxy group having 1 or 2 carbon atoms [a methoxy group or an ethoxy group], an acyl group having 2 or 3 carbon atoms [an acetyl group or a propionyl group], an alkoxycarbonyl group having 2 or 3 carbon atoms [a methoxycarbonyl group or an ethoxycarbonyl group], an acyloxy group having 2 carbon atoms [an acetyloxy group], an acylamino group having 2 carbon atoms [an acetylamino group], a hydroxyalkyl group having 1 to 3 carbon atoms [a hydroxymethyl group, a hydroxyethyl group, or a hydroxypropyl group], an aldehyde group, a hydroxy group, a carboxy group, a sulfo group, a phospho group, a carbamoyl group, a cyano group, an isocyanate group, a mercapto group, a nitro group, a nitroxy group, an isothiocyanate group, a cyanate group, a thiocyanate group, an acetoxy group, an acetamide group, a formyl group, a formyloxy group, a formamide group, a sulfamino group, a sulfino group, a sulfamoyl group, a phosphono group, an acetyl group, a halogen atom, an alkali metal atom, and the like.

In Formula (A), X^{A1} and X^{A2} are separated by L^{A1}, preferably by 1 to 10 atoms, more preferably by 1 to 6 atoms, still more preferably by 1 to 4 atoms, even still more preferably by 1 to 3 atoms, and particularly preferably by 1 or 2 atoms.

In Formula (B), X^{B1} and X^{B3} are separated by L^{B1}, preferably by 1 to 10 atoms, more preferably by 1 to 6 atoms, still more preferably by 1 to 4 atoms, even still more preferably by 1 to 3 atoms, and particularly preferably by 1 or 2 atoms. In addition, X^{B2} and X^{B3} are separated by L^{B2}, preferably by 1 to 10 atoms, more preferably by 1 to 6 atoms, still more preferably by 1 to 4 atoms, even still more preferably by 1 to 3 atoms, and particularly preferably by 1 or 2 atoms.

In Formula (C), X^{C1} and X^{C4} are separated by L^{C1}, preferably by 1 to 10 atoms, more preferably by 1 to 6 atoms, still more preferably by 1 to 4 atoms, even still more preferably by 1 to 3 atoms, and particularly preferably by 1 or 2 atoms. Furthermore, X^{C2} and X^{C4} are separated by L^{C2}, preferably by 1 to 10 atoms, more preferably by 1 to 6 atoms, still more preferably by 1 to 4 atoms, even still more preferably by 1 to 3 atoms, and particularly preferably by 1 or 2 atoms. In addition, X^{C3} and X^{C4} are separated by L^{C3}, preferably by 1 to 10 atoms, more preferably by 1 to 6 atoms, still more preferably by 1 to 4 atoms, even still more preferably by 1 to 3 atoms, and particularly preferably by 1 or 2 atoms.

Furthermore, the description that X^{A1} and X^{A2} are separated by L^{A1} by 1 to 10 atoms means that the number of atoms constituting a molecular chain having the shortest distance, linking X^{A1} and X^{A2}, is 1 to 10. For example, in a case of Formula (A1), X^{A1} and X^{A2} are separated by 2 atoms, and in cases of Formulae (A2) and (A3), X^{A1} and X^{A2} are separated by 3 atoms. The numbers added to the following structural formulae represent the arrangement order of atoms constituting a molecular chain having the shortest distance, linking X^{A1} and X^{A2}.

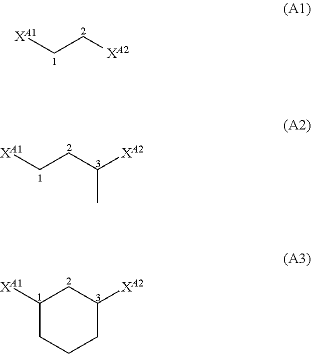

Specific examples of the multidentate ligand include ethanedithiol, 3-mercaptopropionic acid, thiosalicylic acid, thioglycolic acid, 2-aminoethanol, 2-aminoethanethiol, 2-mercaptoethanol, glycolic acid, ethylenediamine, glycine, guanidine, diethylenetriamine, tris(2-aminoethyl)amine, 4-mercaptobutanoic acid, 3-aminopropanol, 3-mercaptopropanol, N-(3-aminopropyl)-1,3-propanediamine, 3-(bis(3-aminopropyl)amino)propan-1-ol, 1-thioglycerol, dimercaprol, 1-mercapto-2-butanol, 1-mercapto-2-pentanol, 3-mercapto-1-propanol, 2,3-dimercapto-1-propanol, diethanolamine, 2-(2-aminoethyl)aminoethanol, dimethylenetriamine, 1,1-oxybismethylamine, 1,1-thiobismethylamine, 2-[(2-aminoethyl)amino]ethanethiol, bis(2-mercaptoethyl)amine, 2-aminoethane-1-thiol, 1-amino-2-butanol, 1-amino-2-pentanol, L-cysteine, D-cysteine, 3-amino-1-propanol, L-homoserine, D-homoserine, aminohydroxyacetic acid, L-lactic acid, D-lactic acid, L-malic acid, D-malic acid, glyceric acid, 2-hydroxybutyric acid, L-tartaric acid, D-tartaric acid, 1,2-benzenedithiol, 1,3-benzenedithiol, 1,4-benzenedithiol, 2-mercaptobenzoic acid, 3-mercaptobenzoic acid, 4-mercaptobenzoic acid, 3-mercapto-2,2-bismercaptomethyl-1-propanol, trimethylolpropane tris(thioglycolate), pentaerythritol tetrakis(mercaptoacetate), dipentaerythritol hexakis(3-mercaptopropionate), dithioerythritol, and derivatives thereof.

The content of the ligand in the dispersion liquid is preferably 1% to 15% by mass with respect to the total mass of the dispersion liquid. The lower limit thereof is preferably 2% by mass or more and more preferably 2.5% by mass or more. The upper limit thereof is preferably 10% by mass or less and more preferably 7% by mass or less.

In addition, the content of the ligand in the dispersion liquid is preferably 10 to 150 mg/mL. The lower limit thereof is preferably 20 mg/mL or more and more preferably 25 mg/mL or more. The upper limit thereof is preferably 100 mg/mL or less and more preferably 70 mg/mL or less.

In addition, the content of the ligand is preferably 10 to 100 parts by mass with respect to 100 parts by mass of the quantum dots. The lower limit thereof is preferably 20 parts by mass or more and more preferably 30 parts by mass or more. The upper limit thereof is preferably 80 parts by mass or less and more preferably 70 parts by mass or less.

The content of the specific ligand in the dispersion liquid is preferably 1% to 15% by mass. The lower limit thereof is preferably 1.5% by mass or more. The upper limit thereof is preferably 10% by mass or less and more preferably 5% by mass or less.

In addition, the content of the specific ligand in the dispersion liquid is preferably 10 to 150 mg/mL. The lower limit thereof is preferably 15 mg/mL or more. The upper limit thereof is preferably 100 mg/mL or less and more preferably 50 mg/mL or less.

In addition, the content of the specific ligand is preferably 10 to 90 parts by mass with respect to 100 parts by mass of the quantum dots. The lower limit thereof is preferably 15 parts by mass or more. The upper limit thereof is preferably 70 parts by mass or less and more preferably 50 parts by mass or less.

### Solvent

The dispersion liquid according to the embodiment of the present invention contains a solvent. The solvent is not particularly limited; however, it is preferably a solvent that hardly dissolves the quantum dots and easily dissolves the ligand. The solvent is preferably an organic solvent. The organic solvent may be a protic solvent or may be an aprotic solvent; however, it is preferably an aprotic solvent and more preferably an aprotic polar solvent.

The boiling point of the solvent is preferably 60° C. to 250° C. The lower limit thereof is preferably 70° C. or higher and more preferably 80° C. or higher. The upper limit thereof is preferably 200° C. or lower and more preferably 190° C. or lower.

Specific examples of the solvent include an alkane [n-hexane, n-octane, or the like], benzene, toluene, N,N-dimethylformamide, dimethyl sulfoxide, N-methylformamide, N,N-dimethylacetamide, propylene carbonate, and ethylene glycol, where the solvent is preferably N,N-dimethylformamide, dimethyl sulfoxide, or N-methylformamide.

The content of the solvent in the dispersion liquid is preferably 50% to 99% by mass, more preferably 70% to 99% by mass, and still more preferably 85% to 98% by mass, with respect to the total mass of the dispersion liquid. The solvent contained in the dispersion liquid may be only one kind or may be a mixed solvent in which two or more kinds are mixed. In a case where the dispersion liquid contains two or more kinds of solvents, it is preferable that the total amount thereof is in the above-described ranges.

### Photoelectric Conversion Film

The photoelectric conversion film according to the embodiment of the present invention is obtained by using the above-described dispersion liquid according to the embodiment of the present invention. Since the photoelectric conversion film according to the embodiment of the present invention has excellent sensitivity to light having a wavelength in the infrared region, a photodetector using the photoelectric conversion film is preferably used as a photodetector that detects light having a wavelength in the infrared region. Therefore, the photoelectric conversion film according to the embodiment of the present invention is preferably used as a photoelectric conversion film for an infrared photodetector.

The light having a wavelength in the infrared region is preferably light having a wavelength of more than 700 nm, more preferably light having a wavelength of 800 nm or more, and still more preferably light having a wavelength of 900 nm or more. In addition, the light having a wavelength in the infrared region is preferably light having a wavelength of 2,000 nm or less and more preferably light having a wavelength of 1,600 nm or less.

The total amount of the quantum dots and the ligand in the photoelectric conversion film is preferably 80% by mass or more, more preferably 90% by mass or more, and still more preferably 95% by mass or more.

### Method for Manufacturing Photoelectric Conversion Film

The method for manufacturing a photoelectric conversion film according to the embodiment of the present invention includes a step of applying the above-described dispersion liquid according to the embodiment of the present invention onto a support to form a composition layer, and a step of drying the composition layer.

The shape, structure, size, and the like of the support onto which the dispersion liquid is applied are not particularly limited and can be appropriately selected according to the intended purpose. The structure of the support may be a monolayer structure or may be a laminated structure. As the support, for example, a support composed of an inorganic material such as silicon, glass, or yttria-stabilized zirconia (YSZ), a resin, a resin composite material, or the like can be used. In addition, an electrode, an insulating film, or the like may be formed on the support. In this case, the dispersion liquid is also applied onto the electrode or the insulating film on the support.

A method for applying the dispersion liquid onto a support is not particularly limited. Examples thereof include coating methods such as a spin coating method, a dipping method, an ink jet method, a dispenser method, a screen printing method, a relief printing method, an intaglio printing method, and a spray coating method.

After forming the composition layer, drying is carried out. By carrying out drying, the solvent remaining in the composition layer can be removed. Further, at least a part of low-boiling point ligands such as ligands having a boiling point of 200° C. or lower are also removed from the composition layer, and thus the spacing between the quantum dots can be made closer.

The drying temperature is preferably 50° C. to 150° C. The upper limit of the drying temperature is preferably 120° C. or lower and more preferably 100° C. or lower. The lower limit of the drying temperature is preferably 55° C. or higher and more preferably 60° C. or higher. In a case where the drying temperature is in the above-described range, it is possible to manufacture a photoelectric conversion film having a small surface defect and a close spacing between the quantum dots.

The drying time is preferably 1 to 30 minutes. The upper limit of the drying time is preferably 20 minutes or less and more preferably 10 minutes or less. The lower limit of the drying time is preferably 2 minutes or more and more preferably 5 minutes or more. In a case where the drying time is in the above-described range, it is possible to manufacture a photoelectric conversion film having a small surface result and a close spacing between the quantum dots.

In the method for manufacturing a photoelectric conversion film according to the embodiment of the present invention, a step of forming a composition layer and a step of drying the composition layer may be alternately repeated a plurality of times.

In the method for manufacturing a photoelectric conversion film according to the embodiment of the present invention, a step of applying a ligand solution may be performed after the step of drying the composition layer. In a case where this step is performed, the ligand coordinated to the quantum dots can be exchanged with a ligand contained in the ligand solution, or a ligand contained in the ligand solution can be coordinated to the quantum dot to suppress the generation of surface defects of the quantum dots.

Examples of the ligand contained in the ligand solution include the ligands described as those that are used in the dispersion liquid according to the embodiment of the present invention. The ligand contained in the ligand solution may be the same as or different from the ligand contained in the dispersion liquid. The ligand solution may contain only one kind or two or more kinds of the ligands. In addition, in the step of applying the ligand solution, two or more kinds of the ligand solutions may be used.

The solvent contained in the ligand solution is preferably selected appropriately according to the kind of the ligand contained in the ligand solution, and it is preferably a solvent that easily dissolves the ligand. In addition, the solvent contained in the ligand solution is preferably an organic solvent having a high dielectric constant. Specific examples thereof include ethanol, acetone, methanol, acetonitrile, dimethylformamide, dimethyl sulfoxide, butanol, and propanol. In addition, the solvent contained in the ligand solution is preferably a solvent that does not easily remain in the photoelectric conversion film to be formed. It is preferably an alcohol, ketone, or nitrile which has a low boiling point, and more preferably methanol, ethanol, acetone, or acetonitrile from the viewpoint of easy drying and easy removal by washing.

A method for applying the ligand solution is the same as the method for applying the dispersion liquid onto the support, and the same applies to the preferred aspect thereof.

In a case where the step of applying the ligand solution is carried out, a step (rinsing step) of bringing the film after the application of the ligand solution into contact with a rinsing liquid to rinse the film may be carried out. In a case where the rinsing step is carried out, it is possible to remove the excessive ligand contained in the film and the ligand eliminated from the quantum dots. In addition, it is possible to remove the remaining solvent and other impurities. The rinsing liquid is preferably an aprotic solvent for the reason that it is easier to effectively remove excess ligands contained in the film and ligands eliminated from the quantum dots, and it is easy to keep the film surface shape uniform by rearranging the surfaces of the quantum dots. Specific examples of the aprotic solvent include acetonitrile, acetone, methyl ethyl ketone, methyl isobutyl ketone, cyclopentanone, diethyl ether, tetrahydrofuran, cyclopentyl methyl ether, dioxane, ethyl acetate, butyl acetate, propylene glycol monomethyl ether acetate, hexane, octane, cyclohexane, benzene, toluene, chloroform, carbon tetrachloride, and dimethylformamide, where acetonitrile and tetrahydrofuran is preferable, and acetonitrile is more preferable.

In addition, the rinsing step may be performed a plurality of times by using two or more kinds of rinsing liquids that differ in polarity (relative permittivity). For example, it is preferable that first, a rinsing liquid having a high relative permittivity (also referred to as a first rinsing liquid) is used to perform rinsing, and then a rinsing liquid having a relative permittivity lower than that of the first rinsing liquid (also referred to as a second rinsing liquid) is used to perform rinsing. The relative permittivity of the first rinsing liquid is preferably 15 to 50, more preferably 20 to 45, and still more preferably 25 to 40. The relative permittivity of the second rinsing liquid is preferably 1 to 15, more preferably 1 to 10, and still more preferably 1 to 5.

The photoelectric conversion film can be manufactured through such a step. The obtained photoelectric conversion film can be used for a photodetector or an image sensor. More specifically, it can be used for a photoelectric conversion film of a photodetector or an image sensor.

### Photodetector

The photodetector according to the embodiment of the present invention has the above-described photoelectric conversion film according to the embodiment of the present invention. Examples of the type of photodetector include a photoconductor-type photodetector and a photodiode-type photodetector. Among the above, a photodiode-type photodetector is preferable for the reason that a high signal-to-noise ratio (SN ratio) is easily obtained.

Since the photoelectric conversion film according to the embodiment of the present invention has excellent sensitivity to the light having a wavelength in the infrared region, the photodetector according to the embodiment of the present invention is preferably used as a photodetector that detects light having a wavelength in the infrared region. That is, the photodetector according to the embodiment of the present invention is preferably used as an infrared photodetector.

The light having a wavelength in the infrared region is preferably light having a wavelength of more than 700 nm, more preferably light having a wavelength of 800 nm or more, and still more preferably light having a wavelength of 900 nm or more. In addition, the light having a wavelength in the infrared region is preferably light having a wavelength of 2,000 nm or less and more preferably light having a wavelength of 1,600 nm or less.

The photodetector may be a photodetector that simultaneously detects light having a wavelength in the infrared region and light having a wavelength in the visible region (preferably light having a wavelength range of 400 to 700 nm).

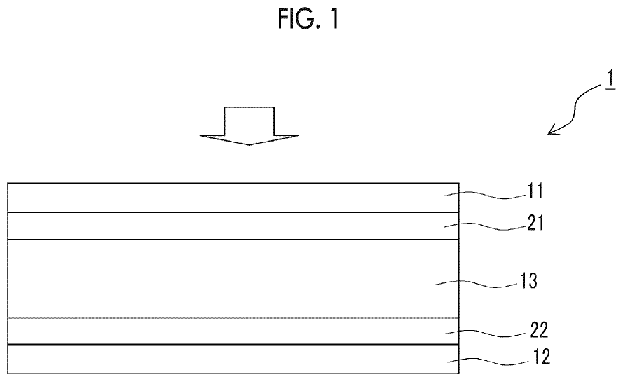

FIG. 1 is a view illustrating an embodiment of a photodetector. FIG. 1 is a view illustrating an embodiment of a photodiode-type photodetector. Furthermore, an arrow in the drawing represents the incidence ray on the photodetector. A photodetector 1 illustrated in FIG. 1 includes a second electrode 12, a first electrode 11 provided to face the second electrode 12, a photoelectric conversion film 13 provided between the second electrode 12 and the first electrode 11, an electron transport layer 21 provided between the first electrode 11 and the photoelectric conversion film 13, and a hole transport layer 22 provided between the second electrode 12 and the photoelectric conversion film 13. The photodetector 1 illustrated in FIG. 1 is used with light incident from above the first electrode 11. Although not illustrated in the drawing, a transparent substrate may be disposed on the surface of the first electrode 11 on the light incident side. Examples of the kind of transparent substrate include a glass substrate, a resin substrate, and a ceramic substrate.

### First Electrode

The first electrode 11 is preferably a transparent electrode formed of a conductive material that is substantially transparent with respect to the wavelength of target light to be detected by the photodetector. Furthermore, in the present specification, the description of “substantially transparent” means that the transmittance of light is 50% or more, preferably 60% or more, and particularly preferably 80% or more. Examples of the material of the first electrode 11 include a conductive metal oxide. Specific examples thereof include tin oxide, zinc oxide, indium oxide, indium tungsten oxide, indium zinc oxide (IZO), indium tin oxide (ITO), and a fluorine-doped tin oxide (FTO).

The film thickness of the first electrode 11 is not particularly limited, and it is preferably 0.01 to 100 μm, more preferably 0.01 to 10 μm, and still more preferably 0.01 to 1 μm. The film thickness of each layer can be measured by observing the cross section of the photodetector 1 using a scanning electron microscope (SEM) or the like.

### Electron Transport Layer

The electron transport layer 21 is a layer having a function of transporting electrons generated in the photoelectric conversion film 13 to an electrode. The electron transport layer is also called a hole block layer. The electron transport layer is formed of an electron transport material capable of exhibiting this function.

Examples of the electron transport material include fullerene compounds such as [6,6]-phenyl-C61-butyric acid methyl ester (PC₆₁BM), perylene compounds such as perylenetetracarboxylic diimide, tetracyanoquinodimethane, titanium oxide, tin oxide, zinc oxide, indium oxide, indium tungsten oxide, indium zinc oxide, indium tin oxide, and fluorine-doped tin oxide. The electron transport material may be a particle.

In addition, it is also preferable that the electron transport layer is composed of a layer containing zinc oxide doped with a metal atom other than Zn. Hereinafter, the zinc oxide doped with a metal atom other than Zn is also referred to as the doped zinc oxide.

The metal atom other than Zn in the doped zinc oxide is preferably a monovalent to trivalent metal atom, more preferably a metal atom including at least one selected from Li, Mg, Al, or Ga, still more preferably Li, Mg, Al, or Ga, and particularly preferably Li or Mg.

In the doped zinc oxide, a proportion of the metal atoms other than Zn to a total of Zn and the metal atoms other than Zn is preferably 1% by atom or more, more preferably 2% by atom or more, and still more preferably 4% by atom or more. From the viewpoint of suppressing an increase in crystal defects, an upper limit of the proportion is preferably 20% by atom or less, more preferably 15% by atom or less, and still more preferably 12% by atom or less. Furthermore, a proportion of the metal atoms other than Zn in the doped zinc oxide can be measured according to a high-frequency inductively coupled plasma (ICP) method.

From the viewpoint of reducing the organic residual component and increasing the area for contact with the photoelectric conversion film, the doped zinc oxide is preferably a particle (a doped zinc oxide particle). In addition, an average particle diameter of the doped zinc oxide particles is preferably 2 to 30 nm. A lower limit value of the average particle diameter of the doped zinc oxide particles is preferably 3 nm or more, and more preferably 5 nm or more. In addition, an upper limit value of the average particle diameter of the doped zinc oxide particles is preferably 20 nm or less, and more preferably 15 nm or less. In a case where the average particle diameter of the doped zinc oxide particles is within the above-described range, it is easy to obtain a film that has a large area for contact with the photoelectric conversion film and has a high flatness. Furthermore, in the present specification, the value of the average particle diameter of the doped zinc oxide particles is an average value of the particle diameters of ten quantum dots which are randomly selected. A transmission electron microscope may be used to measure the particle diameters of the doped zinc oxide particles.

The electron transport layer may be a single-layer film or a laminated film having two or more layers. A thickness of the electron transport layer is preferably 10 to 1,000 nm. An upper limit thereof is preferably 800 nm or less. A lower limit thereof is preferably 20 nm or more, and more preferably 50 nm or more. In addition, the thickness of the electron transport layer is preferably 0.05 to 10 times, more preferably 0.1 to 5 times, and still more preferably 0.2 to 2 times the thickness of the photoelectric conversion film 13.

The electron transport layer may be subjected to an ultraviolet ozone treatment. In particular, in a case of a layer consisting of nanoparticles as the electron transport layer, it is desirable to carry out an ultraviolet ozone treatment. In a case where the ultraviolet ozone treatment is carried out, it is possible to improve the wettability of the quantum dot dispersion liquid on the electron transport layer and decompose or remove the residual organic substances in the electron transport layer, which makes it possible to obtain high element performance. The wavelength of the ultraviolet rays for irradiation can be selected in a wavelength range of 100 to 400 nm. In particular, for the reason that the above-described effect is easily obtained and excessive damage to a film can be avoided, it is preferable that the peak intensity is present in a wavelength range of 200 to 300 nm, and it is more preferable that the peak intensity is present in a wavelength range of 240 to 270 nm. The irradiation intensity of the ultraviolet rays is not particularly limited; however, it is preferably 1 to 100 mW/cm² and more preferably 10 to 50 mW/cm² for the reason that the above-described effect is easily obtained and excessive damage to a film can be avoided. The treatment time is not particularly limited; however, it is preferably 1 to 60 minutes, more preferably 1 to 20 minutes, and still more preferably 3 to 15 minutes, for the same reason as described above.

### Photoelectric Conversion Film

The photoelectric conversion film 13 is composed of a quantum dot film formed by using the above-described dispersion liquid according to the embodiment of the present invention.

The thickness of the photoelectric conversion film 13 is preferably 10 to 1,000 nm. The lower limit of the thickness is preferably 20 nm or more and more preferably 30 nm or more. The upper limit of the thickness is preferably 600 nm or less, more preferably 550 nm or less, still more preferably 500 nm or less, and particularly preferably 450 nm or less. The refractive index of the photoelectric conversion film 13 with respect to light having a target wavelength to be detected by the photodetector can be set to 1.5 to 5.0.

### Hole Transport Layer

The hole transport layer 22 is a layer having a function of transporting holes generated in the photoelectric conversion film 13 to an electrode. The hole transport layer is also called an electron block layer.

The hole transport layer 22 is formed of a hole transport material capable of exhibiting this function. Examples of the hole transport material include PEDOT:PSS (poly(3,4-ethylenedioxythiophene):poly(4-styrenesulfonic acid)), PTB7 (poly{4,8-bis[(2-ethylhexyl)oxy]benzo[1,2-b:4,5-b′]dithiophen-2,6-diyl-lt-alt-3-fluoro-2-[(2-ethylhexyl)carbonyl]thieno[3,4-b]thiophen-4,6-diyl}), PTB7-Th (poly([2,6′-4,8-di(5-ethylhexylthienyl)benzo[1,2-b:3,3-b′]dithiophen]{3-fluoro-2-[(2-ethylhexyl)carbonyl]thieno[3,4-b]thiophendiyl})), PC71BM ([6,6]-phenyl-C71-methyl butyrate), and MoO₃. Furthermore, the organic hole transport material disclosed in paragraph Nos. 0209 to 0212 of JP2001-291534A can also be used. In addition, quantum dots can also be used in the hole transport material. Examples of the quantum dot material constituting the quantum dot include a nanoparticle (a particle having a size of 0.5 nm or more and less than 100 nm) of a general semiconductor crystal [a) a Group IV semiconductor, b) a compound semiconductor of Group IV-IV, Group III-V, or Group II-VI, or c) a compound semiconductor consisting of a combination of three or more of a Group II element, a Group III element, a Group IV element, a Group V element, and a Group VI element]. Specific examples thereof include semiconductor materials having a relatively narrow band gap, such as PbS, PbSe, PbSeS, InN, Ge, InAs, InGaAs, CuInS, CuInSe, CuInGaSe, InSb, HgTe, HgCdTe, Ag₂S, Ag₂Se, Ag₂Te, SnS, SnSe, SnTe, Si, and InP. A ligand may be coordinated to a surface of the quantum dot.

The thickness of the hole transport layer 22 is preferably 5 to 100 nm. A lower limit thereof is preferably 10 nm or more. An upper limit thereof is preferably 50 nm or less, and more preferably 30 nm or less.

### Second Electrode

The second electrode 12 is preferably composed of a metal material including at least one metal atom selected from Ag, Au, Pt, Ir, Pd, Cu, Pb, Sn, Zn, Ti, W, Mo, Ta, Ge, Ni, Al, Cr, and In. Since the second electrode 12 is composed of such a metal material, it is possible for the photodetector to have a high external quantum efficiency and a low dark current. In addition, the above-described conductive metal oxide, a carbon material, a conductive polymer, and the like can also be used for the second electrode 12. The carbon material may be any material having conductivity, and examples thereof include fullerene, a carbon nanotube, graphite, and graphene.

The work function of the second electrode 12 is preferably 4.6 eV or more, more preferably 4.8 to 5.7 eV, and still more preferably 4.9 to 5.3 eV, for the reason that the electron blocking property due to the hole transport layer is increased and the holes generated in the element are easily collected.

The film thickness of the second electrode 12 is not particularly limited, and it is preferably 0.01 to 100 μm, more preferably 0.01 to 10 μm, and particularly preferably 0.01 to 1 μm.

### Blocking Layer

Although not illustrated in the drawing, the photodetector may have a blocking layer between the first electrode 11 and the electron transport layer 21. The blocking layer is a layer having a function of preventing a reverse current. The blocking layer is also called a short circuit prevention layer. Examples of the material that forms the blocking layer include silicon oxide, magnesium oxide, aluminum oxide, calcium carbonate, cesium carbonate, polyvinyl alcohol, polyurethane, titanium oxide, tin oxide, zinc oxide, niobium oxide, and tungsten oxide. The blocking layer may be a single-layer film or a laminated film having two or more layers.

In the photodetector, a wavelength λ of the target light to be detected by the photodetector and an optical path length L^{λ} of the light having the wavelength λ from a surface of the second electrode 12 on a side of the photoelectric conversion film 13 to a surface of the photoelectric conversion film 13 on a side of the first electrode 11 preferably satisfy the relationship of Formula (1-1), and more preferably satisfy the relationship of Formula (1-2). In a case where the wavelength λ and the optical path length L^{λ} satisfy such a relationship, in the photoelectric conversion film 13, it is possible to arrange phases of the light (the incidence ray) incident from the side of the first electrode 11 and phases of the light (the reflected light) reflected on the surface of the second electrode 12, and as a result, the light is intensified by the optical interference effect, whereby it is possible to obtain a higher external quantum efficiency.

$$0.05 + m / 2 \leq {L}^{λ} / λ \leq 0.35 + m / 2 \qquad ( 1 ‐ 1 )$$

$$0.1 + m / 2 \leq {L}^{λ} / λ \leq 0.30 + m / 2 \qquad ( 1 ‐ 2 )$$

In the expression, λ is the wavelength of the target light to be detected by the photodetector,
L^{λ} is the optical path length of the light having the wavelength λ from the surface of the second electrode 12 on the side of the photoelectric conversion film 13 to the surface of the photoelectric conversion film 13 on the side of the first electrode 11, and
m is an integer of 0 or more.

m is preferably an integer of 0 to 4, more preferably an integer of 0 to 3, and still more preferably an integer of 0 to 2. According to this aspect, the transport characteristics of charges such as the hole and the electron are good, and thus it is possible to increase the external quantum efficiency of the photodetector.

Here, the optical path length means the product obtained by multiplying the physical thickness of a substance through which light transmits by the refractive index. To give a description with the photoelectric conversion film 13 as an example, in a case where the thickness of the photoelectric conversion film is denoted by d¹ and the refractive index of the photoelectric conversion film with respect to the light having a wavelength λ¹ is denoted by N¹, the optical path length of the light having the wavelength λ¹ and transmitting through the photoelectric conversion film 13 is N¹×d¹. In a case where the photoelectric conversion film 13 or the hole transport layer 22 is composed of laminated films having two or more layers or in a case where an interlayer is present between the hole transport layer 22 and the second electrode 12, the integrated value of the optical path length of each layer is the optical path length L^{λ}.

### Image Sensor

The image sensor according to the embodiment of the present invention has the above-described photoelectric conversion film according to the embodiment of the present invention. The configuration of the image sensor is not particularly limited as long as it has the photodetector and it is a configuration that functions as an image sensor. Examples of the photodetector include the above-described photodetector.

The image sensor may include an infrared transmitting filter layer. The infrared transmitting filter layer preferably has a low light transmittance in the wavelength band of the visible region, more preferably has an average light transmittance of 10% or less, still more preferably 7.5% or less, and particularly preferably 5% or less, in a wavelength range of 400 to 650 nm.

Examples of the infrared transmitting filter layer include those composed of a resin film containing a coloring material. Examples of the coloring material include a chromatic coloring material such as a red coloring material, a green coloring material, a blue coloring material, a yellow coloring material, a purple coloring material, and an orange coloring material, and a black coloring material. It is preferable that the coloring material contained in the infrared transmitting filter layer forms a black color with a combination of two or more kinds of chromatic coloring materials or is a coloring material containing a black coloring material. Examples of the combination of the chromatic coloring material in a case of forming a black color by a combination of two or more kinds of chromatic coloring materials include the following aspects (C1) to (C7).
(C1) An aspect containing a red coloring material and a blue coloring material.
(C2) An aspect containing a red coloring material, a blue coloring material, and a yellow coloring material.
(C3) An aspect containing a red coloring material, a blue coloring material, a yellow coloring material, and a purple coloring material.
(C4) An aspect containing a red coloring material, a blue coloring material, a yellow coloring material, a purple coloring material, and a green coloring material.
(C5) An aspect containing a red coloring material, a blue coloring material, a yellow coloring material, and a green coloring material.
(C6) An aspect containing a red coloring material, a blue coloring material, and a green coloring material.
(C7) An aspect containing a yellow coloring material and a purple coloring material.

The chromatic coloring material may be a pigment or a dye. The chromatic coloring material may contain a pigment and a dye. The black coloring material is preferably an organic black coloring material. Examples of the organic black coloring material include a bisbenzofuranone compound, an azomethine compound, a perylene compound, and an azo compound.

The infrared transmitting filter layer may further contain an infrared absorber. In a case where the infrared absorber is contained in the infrared transmitting filter layer, the wavelength of the light to be transmitted can be shifted to the longer wave side. Examples of the infrared absorber include a pyrrolo pyrrole compound, a cyanine compound, a squarylium compound, a phthalocyanine compound, a naphthalocyanine compound, a quaterrylene compound, a merocyanine compound, a croconium compound, an oxonol compound, an iminium compound, a dithiol compound, a triarylmethane compound, a pyrromethene compound, an azomethine compound, an anthraquinone compound, a dibenzofuranone compound, a dithiolene metal complex, a metal oxide, and a metal boride.

The spectral characteristics of the infrared transmitting filter layer can be appropriately selected according to the use application of the image sensor. Examples of the filter layer include those that satisfy any one of the following spectral characteristics of (1) to (5).
(1): A filter layer in which the maximum value of the light transmittance in the film thickness direction in a wavelength range of 400 to 750 nm is 20% or less (preferably 15% or less and more preferably 10% or less), and the minimum value of the light transmittance in the film thickness direction in a wavelength range of 900 to 1,500 nm is 70% or more (preferably 75% or more and more preferably 80% or more).
(2): A filter layer in which the maximum value of the light transmittance in the film thickness direction in a wavelength range of 400 to 830 nm is 20% or less (preferably 15% or less and more preferably 10% or less), and the minimum value of the light transmittance in the film thickness direction in a wavelength range of 1,000 to 1,500 nm is 70% or more (preferably 75% or more and more preferably 80% or more).
(3): A filter layer in which the maximum value of the light transmittance in the film thickness direction in a wavelength range of 400 to 950 nm is 20% or less (preferably 15% or less and more preferably 10% or less), and the minimum value of the light transmittance in the film thickness direction in a wavelength range of 1,100 to 1,500 nm is 70% or more (preferably 75% or more and more preferably 80% or more).
(4): A filter layer in which the maximum value of the light transmittance in the film thickness direction in a wavelength range of 400 to 1,100 nm is 20% or less (preferably 15% or less and more preferably 10% or less), and the minimum value thereof in a wavelength range of 1,400 to 1,500 nm is 70% or more (preferably 75% or more and more preferably 80% or more).
(5): A filter layer in which the maximum value of the light transmittance in the film thickness direction in a wavelength range of 400 to 1,300 nm is 20% or less (preferably 15% or less and more preferably 10% or less), and the minimum value thereof in a wavelength range of 1,600 to 2,000 nm is 70% or more (preferably 75% or more and more preferably 80% or more).

Further, as the infrared transmitting filter, the films disclosed in JP2013-077009A, JP2014-130173A, JP2014-130338A, WO2015/166779A, WO2016/178346A, WO2016/190162A, WO2018/016232A, JP2016-177079A, JP2014-130332A, and WO2016/027798A can be used. As the infrared transmitting filter, two or more filters may be used in combination, or a dual bandpass filter that transmits through two or more specific wavelength ranges with one filter may be used.

The image sensor may include an infrared shielding filter for the intended purpose of improving various performances such as noise reduction. Specific examples of the infrared shielding filter include the filters disclosed in WO2016/186050A, WO2016/035695A, JP6248945B, WO2019/021767A, JP2017-067963A, and JP6506529B.

The image sensor may include a dielectric multi-layer film. Examples of the dielectric multi-layer film include those in which a plurality of layers are laminated by alternately laminating a dielectric thin film having a high refractive index (a high refractive index material layer) and a dielectric thin film having a low refractive index (a low refractive index material layer). The number of lamination layers of the dielectric thin film in the dielectric multi-layer film is not particularly limited, but is preferably 2 to 100 layers, more preferably 4 to 60 layers, and still more preferably 6 to 40 layers. The material that is used for forming the high refractive index material layer is preferably a material having a refractive index of 1.7 to 2.5. Specific examples thereof include Sb₂O₃, Sb₂S₃, Bi₂O₃, CeO₂, CeF₃, HfO₂, La₂O₃, Nd₂O₃, Pr₆O₁₁, Sc₂O₃, SiO, Ta₂O₅, TiO₂, TlCl, Y₂O₃, ZnSe, ZnS, and ZrO₂. The material that is used for forming the low refractive index material layer is preferably a material having a refractive index of 1.2 to 1.6. Specific examples thereof include Al₂O₃, BiF₃, CaF₂, LaF₃, PbCl₂, PbF₂, LiF, MgF₂, MgO, NdF₃, SiO₂, Si₂O₃, NaF, ThO₂, ThF₄, and Na₃AlF₆. The method for forming the dielectric multi-layer film is not particularly limited; however, examples thereof include ion plating, a vacuum vapor deposition method using an ion beam or the like, a physical vapor deposition method (PVD method) such as sputtering, and a chemical vapor deposition method (CVD method). The thickness of each of the high refractive index material layer and the low refractive index material layer is preferably 0.1 λ to 0.5 λ in a case where the wavelength of the light to be blocked is λ (nm). Specific examples of the usable dielectric multi-layer film include the films disclosed in JP2014-130344A and JP2018-010296A.

In the dielectric multi-layer film, the transmission wavelength band is preferably present in the infrared region (preferably a wavelength range having a wavelength of more than 700 nm, more preferably a wavelength range having a wavelength of more than 800 nm, and still more preferably a wavelength range having a wavelength of more than 900 nm). The maximum transmittance in the transmission wavelength band is preferably 70% or more, more preferably 80% or more, and still more preferably 90% or more. In addition, the maximum transmittance in the shielding wavelength band is preferably 20% or less, more preferably 10% or less, and still more preferably 5% or less. In addition, the average transmittance in the transmission wavelength band is preferably 60% or more, more preferably 70% or more, and still more preferably 80% or more. In addition, in a case where the wavelength at which the maximum transmittance is exhibited is denoted by a central wavelength λₜ₁, the wavelength range of the transmission wavelength band is preferably the central wavelength λₜ₁±100 nm, more preferably the central wavelength λₜ₁±75 nm, and still more preferably the central wavelength λₜ₁±50 nm.

The dielectric multi-layer film may have only one transmission wavelength band (preferably, a transmission wavelength band having a maximum transmittance of 90% or more) or may have a plurality of transmission wavelength bands.

The image sensor may include a color separation filter layer. Examples of the color separation filter layer include a filter layer including colored pixels. Examples of the kind of colored pixel include a red pixel, a green pixel, a blue pixel, a yellow pixel, a cyan pixel, and a magenta pixel. The color separation filter layer may include colored pixels having two or more colors or having only one color. It can be appropriately selected according to the use application and the intended purpose. For example, the filter disclosed in WO2019/039172A can be used.

In addition, in a case where the color separation layer includes colored pixels having two or more colors, the colored pixels of the respective colors may be adjacent to each other, or a partition wall may be provided between the respective colored pixels. The material of the partition wall is not particularly limited. Examples thereof include organic materials such as a siloxane resin and a fluororesin, and inorganic particles such as a silica particle. In addition, the partition wall may be composed of a metal such as tungsten and aluminum.

It is noted that in a case where the image sensor includes an infrared transmitting filter layer and a color separation layer, it is preferable that the color separation layer is provided on an optical path different from the infrared transmitting filter layer. In addition, it is also preferable that the infrared transmitting filter layer and the color separation layer are disposed two-dimensionally. It is noted that the description that the infrared transmitting filter layer and the color separation layer are disposed two-dimensionally means that at least parts of both are present on the same plane.

The image sensor may include an interlayer such as a planarizing layer, an underlying layer, or an intimate attachment layer, an anti-reflection film, and a lens. As the anti-reflection film, for example, a film produced from the composition disclosed in WO2019/017280A can be used. As the lens, for example, the structure disclosed in WO2018/092600A can be used.

### EXAMPLES

Hereinafter, the present invention will be described in detail with reference to Examples. Materials, amounts used, proportions, treatment details, treatment procedures, and the like shown in the following examples can be appropriately changed without departing from the gist of the present invention. Therefore, the scope of the present invention is not limited to the specific examples described below.

### Production of Quantum Dot Dispersion Liquid

### Dispersion Liquids 1 to 24 and Comparative Dispersion Liquid 1

1 mL of an octane dispersion liquid of quantum dots (concentration of quantum dots: 50 mg/mL, concentration of oleic acid: 50 mg/mL) having a surface to which oleic acid was coordinated, the quantum dots being described in the table below, 0.5 g of a ligand 1 and 0.1 g of a ligand 2 described in the table below, and 5 mL of the solvent described in the table below were measured and put in a centrifugal separation tube, and the resultant mixture was vigorously stirred for 10 minutes. Next, 30 mL of octane was added thereto, followed by vigorous stirring for 1 minute. Then, the operation of removing the upper layer as the octane layer was repeated twice. Then, an excessive amount of toluene was added thereto, followed by centrifugal separation at 4,000 rpm for 5 minutes. The obtained precipitate was dried at 25° C. under a pressure of 1.0 mmHg for 30 minutes, 0.5 mL of the solvent described in the table below was added thereto, and the resultant mixture was stirred for 1 hour to obtain a ligand-exchanged quantum dot dispersion liquid (dispersion liquids 1 to 24 and a comparative dispersion liquid 1). It is noted that all of the above-described operations were carried out under nitrogen.

The obtained quantum dot dispersion liquid was allowed to stand at 25° C. under nitrogen for 1 week or 1 month, and then the presence or absence of aggregates was visually checked to evaluate the dispersibility.
A: Aggregation was not confirmed even after being allowed to stand for 1 month.
B: Although there was slight aggregation after being allowed to stand for 1 month, no aggregation was confirmed after being allowed to stand for 1 week.
C: In the production step of the quantum dot dispersion liquid, the precipitate after centrifugation separation was not dispersed.

TABLE 1

| | Quantum Dot | | | | | | | |
|---|---|---|---|---|---|---|---|---|
| | | Maximal | | | | | | Evalu- |
| | | Absorption | | | | | | ation |
| | | in terms of | Band | Ligand 1 | | Ligand 2 | Sol- | Dispers- |
| | Kind | Absorbance | Gap | Kind | pKa | Kind | vent | ibility |
| Dispersion Liquid 1 | PbS | 1441 | 0.86 | Phenyl Phosphonic Acid | 1.9 | | DMF | A |
| Dispersion Liquid 2 | PbS | 1441 | 0.86 | Methanesulfonic Acid | 1.8 | | DMF | A |
| Dispersion Liquid 3 | PbS | 1441 | 0.86 | Trifluoroacetic Acid | 0.5 | | DMF | A |
| Dispersion Liquid 4 | PbS | 1441 | 0.86 | Bromoacetic Acid | 2.7 | | DMF | A |
| Dispersion Liquid 5 | PbS | 1441 | 0.86 | 3-Phosphorylpropionic Acid | 2.0 | | DMF | A |
| Dispersion Liquid 6 | PbS | 1441 | 0.86 | Glycine-N,N-bis(methylenephosphonic acid) | 0.4 | | DMF | A |
| Dispersion Liquid 7 | PbS | 1441 | 0.86 | 2-Chloroethyl Phosphoric Acid | 2.0 | | DMF | A |
| Dispersion Liquid 8 | PbS | 1441 | 0.86 | Phenyl Phosphate | 1.3 | | DMF | A |
| Dispersion Liquid 9 | PbS | 1441 | 0.86 | Dimethyl Phosphate | 1.2 | | DMF | A |
| Dispersion Liquid 10 | PbS | 1441 | 0.86 | Phenyl Phosphonic Acid | 1.9 | Bromoacetic Acid | DMF | A |
| Dispersion Liquid 11 | PbS | 1441 | 0.86 | Phenyl Phosphonic Acid | 1.9 | Chloroethyl Phos- | DMF | A |
| | | | | | | phonic Acid | | |
| Dispersion Liquid 12 | PbS | 1441 | 0.86 | Phenyl Phosphonic Acid | 1.9 | Zinc(II) Iodide | DMF | A |
| Dispersion Liquid 13 | PbS | 1441 | 0.86 | Zinc(II) Trifluoromethanesulfonate | −3.9 | | DMF | B |
| Dispersion Liquid 14 | PbS | 1441 | 0.86 | Phenyl Phosphonic Acid | 1.9 | | DMSO | A |
| Dispersion Liquid 15 | PbS | 1441 | 0.86 | Phenyl Phosphonic Acid | 1.9 | | NMF | A |
| Dispersion Liquid 16 | PbS | 936 | 1.32 | Phenyl Phosphonic Acid | 1.9 | | DMF | A |
| Dispersion Liquid 17 | PbS | 1550 | 0.8 | Phenyl Phosphonic Acid | 1.9 | | DMF | A |
| Dispersion Liquid 18 | InAs | 936 | 1.32 | Phenyl Phosphonic Acid | 1.9 | | DMF | A |
| Dispersion Liquid 19 | InAs | 936 | 1.32 | Phenyl Phosphonic Acid | 1.9 | Zinc(III) Bromide | DMF | A |
| Dispersion Liquid 20 | InAs | 1442 | 0.86 | Phenyl Phosphonic Acid | 1.9 | | DMF | A |
| Dispersion Liquid 21 | InAs | 1442 | 0.86 | Dimethyl Phosphate | 1.2 | | DMF | A |
| Dispersion Liquid 22 | InPAs | 1443 | 0.86 | Phenyl Phosphonic Acid | 1.9 | | DMF | A |
| Dispersion Liquid 23 | InAsSb | 1442 | 0.86 | Phenyl Phosphonic Acid | 1.9 | | DMF | A |
| Dispersion Liquid 24 | InSb | 1442 | 0.86 | Phenyl Phosphonic Acid | 1.9 | | DMF | A |
| Comparative | PbS | 1441 | 0.86 | Acetic Acid | 4.8 | | DMF | C |
| Dispersion | | | | | | | | |
| Liquid1 | | | | | | | | |

Details of the materials indicated by abbreviations in the above tables are as follows.
DMF: N,N-dimethylformamide
DMSO: Dimethyl sulfoxide

The pKa values of the ligands in the above table are values determined by calculation using software (Advanced Chemistry Development (ACD/Labs) Software V8.14 for Solaris (1994-2007 ACD/Labs)).

As shown in the table above, all of the dispersion liquids 1 to 24 had excellent dispersibility.

### Dispersion Liquid 25

The dispersion liquid 1 and the dispersion liquid 7 were mixed at a volume ratio of 1:1 to obtain a dispersion liquid 25. In a case where the dispersibility of the dispersion liquid 25 was evaluated by the same method as described above, the evaluation result of A was obtained.

### Production of Zinc Oxide Particle Dispersion Liquid

### Zinc Oxide Particle Dispersion Liquid 1

1.5 mmol of zinc acetate dihydrate and 15 ml of dimethyl sulfoxide (DMSO) were measured and put in a flask, and the resultant mixture was stirred to obtain a zinc acetate solution.

A tetramethylammonium chloride (TMACl) solution obtained by dissolving 4 mmol of TMACl in 4 ml of methanol and a potassium hydroxide (KOH) solution obtained by dissolving 4mmol of KOH in 4 ml of methanol were produced. The KOH solution was slowly added while vigorously stirring the TMACl solution, and after stirring for 30 minutes, insoluble components were removed through a filter having a pore diameter of 0.45 μm to obtain a tetramethylammonium hydroxide (TMAH) solution.

6 ml of the TMAH solution was added to the zinc acetate solution contained in the flask at a dropwise addition rate of 6 ml/min. After being held for 1 hour, the reaction solution was recovered. An excessive amount of acetone was added to the reaction solution, centrifugal separation was carried out at 10,000 rpm for 10 minutes, and then the supernatant was removed. After dispersing the precipitate in methanol, the precipitate was precipitated again with acetone, 5 ml of ethanol and 80 μl of aminoethanol were added thereto, and ultrasonic dispersion was carried out to obtain a zinc oxide particle dispersion liquid 1 in which the concentration of the non-doped zinc oxide particles was about 30 mg/mL.

### Manufacturing of Photodetector

### Examples 1 to 17 and 25

An indium tin oxide (ITO) film having a thickness of about 100 nm was formed on a quartz glass by a sputtering method to form a first electrode. Next, a titanium oxide film having a thickness of about 20 nm was formed on the ITO film (first electrode) by a sputtering method to form an electron transport layer. Next, the dispersion liquid described in the table below was added dropwise onto the titanium oxide film (electron transport layer) in a glove box, and then spin coating was carried out at 1,000 rpm, and dried at 120° C. for 10 minutes to form a quantum dot film. The step of forming the quantum dot film was repeated 4 times to form a photoelectric conversion film having a thickness of 180 nm. Next, the photoelectric conversion film was dried in a glove box for 10 hours.

Next, a dichlorobenzene solution of PTB7 (poly({4,8-bis[(2-ethylhexyl)oxy]benzo[1,2-b:4,5-b′]dithiophen-2,6-diyl}{3-fluoro-2-[(2-ethylhexyl)carbonyl]thieno[3,4-b]thiophendiyl})) (concentration: 5 mg/mL) was spin-coated at 2,000 rpm onto the photoelectric conversion film, and then dried in a glove box for 10 hours to form a hole transport layer.

Next, a MoO₃ film having a thickness of 5 nm was formed on the hole transport layer by a vacuum vapor deposition method through a metal mask, and then an Au film (the second electrode) having a thickness of 100 nm was formed to manufacture a photodiode-type photodetector.

### Examples 18 to 24

An indium tin oxide (ITO) film having a thickness of about 100 nm was formed on a quartz glass by a sputtering method to form a first electrode.

Next, the ITO film (first electrode) was subjected to spin coating with a solution obtained by dissolving 1 g of zinc acetate dihydrate and 284 μl of ethanolamine in 10 ml of methoxyethanol at 3,000 rpm. Then, heating was carried out at 200° C. for 30 minutes to form a sol-gel film of zinc oxide having a thickness of about 40 nm. Next, a step of dropwise adding the zinc oxide particle dispersion liquid 1 onto the sol-gel film, carrying out spin coating at 2,500 rpm, and carrying out heating at 70° C. for 30 minutes was carried out twice. Then, using UVO-CLEANER MODEL 144AX-100 manufactured by Jelight Company Inc., an ultraviolet ozone treatment was carried out for 5 minutes under a condition of 30 mW/cm² (wavelength peak: 254 nm) to form a particle film of zinc oxide having a thickness of about 130 nm, whereby an electron transport layer was formed.

Next, a dispersion liquid described in the table below was added dropwise onto the electron transport layer, and the resultant mixture was spin-coated at 1,000 rpm and dried at 120° C. for 10 minutes to form a quantum dot film. The step of forming the quantum dot film was repeated 4 times to form a photoelectric conversion film having a thickness of 180 nm. Next, the photoelectric conversion film was dried in a glove box for 10 hours.

Next, a dichlorobenzene solution of PTB7 (poly({4,8-bis[(2-ethylhexyl)oxy]benzo[1,2-b:4,5-b′]dithiophen-2,6-diyl}{3-fluoro-2-[(2-ethylhexyl)carbonyl]thieno[3,4-b]thiophendiyl})) (concentration: 5 mg/mL) was spin-coated at 2,000 rpm onto the photoelectric conversion film, and then dried in a glove box for 10 hours to form a hole transport layer.

Next, a MoO₃ film having a thickness of 5 nm was formed on the hole transport layer by a vacuum vapor deposition method through a metal mask, and then an Au film (the second electrode) having a thickness of 100 nm was formed to manufacture a photodiode-type photodetector.

### Comparative Example 1

A photodetector was manufactured by the same method as in Example 1, except that in the step of forming the photoelectric conversion film, a comparative dispersion liquid 2 which was an octane dispersion liquid of PbS quantum dots (concentration of PbS quantum dots: 100 mg/mL, concentration of oleic acid: 50 mg/mL) in which oleic acid was coordinated on the surface was used instead of the dispersion liquid 1, and the photoelectric conversion film was formed to have a thickness of 220 nm.

### Evaluation

### Evaluation of Electrical Characteristics 1

For the photodetectors of Examples 1 to 25 and Comparative Example 1, an external quantum efficiency (EQE) and a dark current were evaluated using a semiconductor parameter analyzer (C4156, manufactured by Agilent Technologies, Inc.).

First, the current-voltage characteristics (I-V characteristics) were measured while sweeping the voltage from 0 V to −2 V in a state of not carrying out irradiation with light, and the dark current value was evaluated. Here, regarding the dark current value, a value at −1 V was used as the dark current value. Subsequently, the I-V characteristics were measured while sweeping the voltage from 0 V to −2 V in a state of carrying out irradiation with monochromatic light having a wavelength of 940 nm, 1,450 nm, or 1,550 nm. A value obtained by subtracting the dark current value from the current value in a state where −1 V was applied was defined as the photocurrent value, and the external quantum efficiency (EQE) was calculated from the photocurrent value.

In addition, in Examples 16, 18, and 19, the external quantum efficiency and the dark current were measured by carrying out irradiation with monochromatic light having a wavelength of 940 nm. It is noted that in Examples 1 to 15 and 20 to 25 and Comparative Example 1, the external quantum efficiency and the dark current were measured by carrying out irradiation with monochromatic light having a wavelength of 1,450 nm. In addition, in Example 17, the external quantum efficiency and the dark current were measured by carrying out irradiation with monochromatic light having a wavelength of 1,550 nm.

### Evaluation of Electrical Characteristics 2

For the photodetectors of Examples 20 to 24 and Comparative Example 1, an external quantum efficiency (EQE) and a dark current were evaluated using a semiconductor parameter analyzer (C4156, manufactured by Agilent Technologies, Inc.).

First, the current-voltage characteristics (I-V characteristics) were measured while sweeping the voltage from 0 V to −5 V in a state of not carrying out irradiation with light, and the dark current value was evaluated. Here, regarding the dark current value, a value at −5 V was used as the dark current value. Subsequently, the I-V characteristics were measured while sweeping the voltage from 0 V to −5 V in a state of carrying out irradiation with monochromatic light having a wavelength of 1,450 nm. A value obtained by subtracting the dark current value from the current value in a state where −5 V was applied was defined as the photocurrent value, and the external quantum efficiency (EQE) was calculated from the photocurrent value.

TABLE 2

| | | | Electrical | | Electrical | |
|---|---|---|---|---|---|---|
| | | | Characteristics 1 | | Characteristics 2 | |
| | | | EQE | Dark Current | EQE | Dark Current |
| | | Electron Transport Layer | [%] | [μA/cm²] | [%] | [μA/cm²] |
| Example 1 | Dispersion Liquid 1 | Titanium Oxide Film | 44.5 | 0.32 | — | — |
| Example 2 | Dispersion Liquid 2 | Titanium Oxide Film | 49.1 | 6.01 | — | — |
| Example 3 | Dispersion Liquid 3 | Titanium Oxide Film | 48.2 | 4.27 | — | — |
| Example 4 | Dispersion Liquid 4 | Titanium Oxide Film | 48.3 | 0.9 | — | — |
| Example 5 | Dispersion Liquid 5 | Titanium Oxide Film | 45.3 | 0.5 | — | — |
| Example 6 | Dispersion Liquid 6 | Titanium Oxide Film | 46.5 | 2.98 | — | — |
| Example 7 | Dispersion Liquid 7 | Titanium Oxide Film | 47.5 | 0.72 | — | — |
| Example 8 | Dispersion Liquid 8 | Titanium Oxide Film | 42.1 | 0.35 | — | — |
| Example 9 | Dispersion Liquid 9 | Titanium Oxide Film | 48.5 | 0.66 | — | — |
| Example 10 | Dispersion Liquid 10 | Titanium Oxide Film | 47.5 | 0.71 | — | — |
| Example 11 | Dispersion Liquid 11 | Titanium Oxide Film | 46.1 | 0.51 | — | — |
| Example 12 | Dispersion Liquid 12 | Titanium Oxide Film | 50 | 1.11 | — | — |
| Example 13 | Dispersion Liquid 13 | Titanium Oxide Film | 48.2 | 5.68 | — | — |
| Example 14 | Dispersion Liquid 14 | Titanium Oxide Film | 44.6 | 0.35 | — | — |
| Example 15 | Dispersion Liquid 15 | Titanium Oxide Film | 44.4 | 0.33 | — | — |
| Example 16 | Dispersion Liquid 16 | Titanium Oxide Film | 50.2 | 0.02 | — | — |
| Example 17 | Dispersion Liquid 17 | Titanium Oxide Film | 43.5 | 0.48 | — | — |
| Example 18 | Dispersion Liquid 18 | Particle Film of Zinc Oxide | 9.1 | 0.01 | — | — |
| Example 19 | Dispersion Liquid 19 | Particle Film of Zinc Oxide | 25.5 | 0.01 | — | — |
| Example 20 | Dispersion Liquid 20 | Particle Film of Zinc Oxide | 0.5 | 0.31 | 5.1 | 10.1 |
| Example 21 | Dispersion Liquid 21 | Particle Film of Zinc Oxide | 0.5 | 0.61 | 5.2 | 14.1 |
| Example 22 | Dispersion Liquid 22 | Particle Film of Zinc Oxide | 0.4 | 0.44 | 4.4 | 11.9 |
| Example 23 | Dispersion Liquid 23 | Particle Film of Zinc Oxide | 0.5 | 0.48 | 5.3 | 12.4 |
| Example 24 | Dispersion Liquid 24 | Particle Film of Zinc Oxide | 0.4 | 0.5 | 4.8 | 13 |
| Example 25 | Dispersion Liquid 25 | Titanium Oxide Film | 46.5 | 0.59 | — | — |
| Comparative | Comparative Dispersion | Titanium Oxide Film | 0.1 | 0.003 | 0.1 | 0.01 |
| Example 1 | Liquid 2 | | | | | |

As described in the above table, it was confirmed that the external quantum efficiency (EQE) of the photodetector of Example was significantly high as compared with the external quantum efficiency (EQE) of Comparative Example 1.

In a case of manufacturing an image sensor using the photodetector obtained in Examples by using an optical filter produced according to the method described in WO2016/186050A and WO2016/190162A and together with a publicly known method, it is possible to obtain an image sensor having good visibility and infrared imaging performance.

### EXPLANATION OF REFERENCES

1: photodetector
11: first electrode
12: second electrode
13: photoelectric conversion film
21: electron transport layer
22: hole transport layer

What is claimed is:

1. A dispersion liquid comprising:
quantum dots having a band gap of 1.35 eV or less;
a ligand; and
a solvent,
wherein a content of the quantum dots in a component obtained by removing the solvent and the ligand from the dispersion liquid is 50% by mass or more, and
the ligand contains a compound having a pKa of 3 or less or a salt of the compound.

2. The dispersion liquid according to claim 1,
wherein a molecular weight of the compound having a pKa of 3 or less is 50 to 500.

3. The dispersion liquid according to claim 1,
wherein the compound having a pKa of 3 or less is a compound having at least one functional group selected from the group consisting of a carboxy group, a phospho group, a phosphonic acid group, a sulfonimide group, and a sulfo group.

4. The dispersion liquid according to claim 1,
wherein the compound having a pKa of 3 or less is a compound having at least one functional group selected from the group consisting of a phospho group and a phosphonic acid group.

5. The dispersion liquid according to claim 1,
wherein the quantum dots contain at least one atom selected from the group consisting of Ga, Ge, P, As, Se, In, Sn, Sb, Te, Pb, Bi, Ag, Cu, and Hg.

6. The dispersion liquid according to claim 1,
wherein the quantum dots contain at least one atom selected from the group consisting of P, As, Sb, and In.

7. The dispersion liquid according to claim 1,
wherein the quantum dots have a maximal absorption in terms of absorbance in a wavelength range of 900 to 1,700 nm.

8. A photoelectric conversion film obtained by using the dispersion liquid according to claim 1.

9. A method for manufacturing a photoelectric conversion film, comprising:
applying the dispersion liquid according to claim 1 onto a support to form a composition layer; and
drying the composition layer.

10. A photodetector comprising:
the photoelectric conversion film according to claim 8.

11. An image sensor comprising:
the photoelectric conversion film according to claim 8.
